(19) United States
(12) Patent Application Publication
(10) Pub. No.: US 2019/0243251 A1
(43) Pub. Date: Aug. 8, 2019

(54) AQUEOUS SOLUTION FOR RESIST PATTERN COATING AND PATTERN FORMING METHOD USING THE SAME

(71) Applicant: NISSAN CHEMICAL CORPORATION, Tokyo (JP)

(72) Inventors: Tokio NISHITA, Toyama-shi (JP); Rikimaru SAKAMOTO, Toyama-shi (JP)

(73) Assignee: NISSAN CHEMICAL CORPORATION, Tokyo (JP)

(21) Appl. No.: 16/343,342

(22) PCT Filed: Oct. 13, 2017
(86) PCT No.: PCT/JP2017/037190

§ 371 Date: Apr. 18, 2019

(30) Foreign Application Priority Data
Oct. 19, 2016 (JP) 2016-205488

(51) Int. Cl. G03F 7/40; G03F 7/32; C09D 105/16; G03F 7/20; G03F 7/38; G03F 7/16

(52) U.S. Cl. CPC G03F 7/40; G03F 7/322; C09D 105/16; G03F 7/168; G03F 7/38; G03F 7/162; G03F 7/20

(57) ABSTRACT

A novel aqueous solution for resist pattern coating including, as an A component, a cyclodextrin selected from the group consisting of α-cyclodextrin, β-cyclodextrin, and γ-cyclodextrin, or a derivative of the cyclodextrin, as a B component, a solvent containing water as a main component, and as a component C, an organic sulfonic acid of Formula (2):

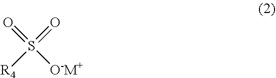

(wherein R₄ is alkyl or fluorinated alkyl group, or an aromatic group having at least one substituent, and M⁺ is a hydrogen ion, an ammonium ion, a pyridinium ion, or an imidiazolium ion), or a salt thereof, wherein the content of the A component is 0.1% by mass to 10% by mass relative to 100% by mass of the total aqueous solution, and wherein the content of the organic sulfonic acid or the salt thereof is 0.01% by mass to 50% by mass relative to 100% by mass of the component A.

### TECHNICAL FIELD

The present invention relates to an aqueous solution for resist pattern coating capable of preventing collapse of a linear or columnar resist pattern and making the linear or columnar resist pattern finer or increasing the hole diameter of a resist pattern with holes. Further, the present invention relates to a method for forming a pattern using the aqueous solution and a method for forming an inverted pattern using the aqueous solution.

### BACKGROUND ART

In production of semiconductor devices, microprocessing has been carried out through lithography using a resist composition. The microprocessing is a processing method in which a thin film is formed from a photoresist composition on a semiconductor substrate such as a silicon wafer, irradiated with active light such as ultraviolet light through a mask pattern including a pattern of a device, and developed, and the substrate is etched through the obtained photoresist pattern as a protective film to form fine concaves and convexes corresponding to the pattern on a surface of the substrate. In recent years, an increase in degree of integration of semiconductor devices has advanced, and as active light, an ArF excimer laser (wavelength: 193 nm) is used instead of an i line (wavelength: 365 nm) and a KrF excimer laser (wavelength: 248 nm). The wavelength of active light is decreased. Currently, lithography using EUV (abbreviation of extreme ultraviolet light, wavelength: 13.5 nm) exposure, which is further micro fabrication technology, is investigated. However, the development of a high-power EUV light source delays. Therefore, lithography using EUV exposure (mass production) have not yet applied to practical use.

A method for making a resist pattern finer by coating the resist pattern and a coating material used for this method are known (e.g., Patent Documents 1 to 4). By this method, a resist pattern produced through lithography using exposure by an ArF excimer laser which has been already put to practical use can be made much finer.

### PRIOR ART DOCUMENTS

### Patent Documents

Patent Document 1: Japanese Patent Application Publication No. 2001-281886 (JP 2001-281886 A)
Patent Document 2: Japanese Patent Application Publication No. 2010-49247 (JP 2010-49247 A)
Patent Document 3: Japanese Patent Application Publication No. 2011-257499 (JP 2011-257499 A)
Patent Document 4: Japanese Patent Application Publication No. 2013-145290 (JP 2013-145290 A)

### SUMMARY OF THE INVENTION

### Problem to be Solved by the Invention

In an aqueous solution containing a water-soluble resin described in Patent Document 1, water having a higher surface tension than that of an organic solvent is used as a solvent, and thus application properties to a resist pattern are low. Therefore, it is necessary to add a surfactant or use a mixture of a water-soluble alcohol with water. A composition for making a resist pattern finer described in Patent Document 2 is a solution containing no polymer, and thus the reduction ratio tends to vary depending on the shape of the resist pattern to be made finer. A pattern miniaturization agent described in Patent Document 3 contains an acid generator component, and thus it is necessary that the pattern miniaturization agent be baked at a temperature of 130° C. or higher after applying or an exposure step be performed after applying the pattern miniaturization agent. In a method for forming a fine pattern described in Patent Document 4, a resist pattern formed by a negative type developing process is narrowed, that is, a coating film is formed on the resist pattern and heated to reduce the space width in the resist pattern. Accordingly, the method for forming a fine pattern does not aim to reduce the width or diameter of the resist pattern.

The present invention is to solve the above-mentioned problems. An object of the present invention is to provide an aqueous solution for resist pattern coating that exhibits good application properties during applying the aqueous solution to a resist pattern without drying the resist pattern after a development treatment and a rinsing treatment, and can reduce the Laplace pressure in a linear or columnar resist pattern to prevent collapse of the resist pattern. Another object of the present invention is to provide an aqueous solution for resist pattern coating containing an organic sulfonic acid or a salt thereof that can reduce the size of a linear or columnar resist pattern or increase the diameter of holes of a resist pattern. Yet another object of the present invention is to provide a method for forming a resist pattern using the aqueous solution and a method for forming an inverted pattern using the aqueous solution.

### Means for Solving the Problems

In order to achieve the objects, an aqueous solution for resist pattern coating that can form a finer pattern than a pattern formed from a conventional fine pattern-forming composition, can easily control the decrement in size of a linear or columnar resist pattern or the increment in diameter of holes in a resist pattern, contains as a solvent water and optionally a specific water-soluble organic solvent such as isopropyl alcohol, and can be used in a general development cup provided in a coater-developer due to excellent compatibility with another solution used in the development cup (e.g., a developer and a rinsing liquid containing a surfactant) is found in the present invention.

A first aspect of the present invention is an aqueous solution for resist pattern coating comprising, as a component A, a cyclodextrin selected from the group consisting of α-cyclodextrin, β-cyclodextrin, and γ-cyclodextrin, or a derivative of the cyclodextrin, and as a component B, a solvent containing water as a main component, wherein the content of the component A is 0.1% by mass to 10% by mass relative to 100% by mass of the aqueous solution.

The derivative of the cyclodextrin is, for example, a compound having at least one unit of Formula (1a), (1b), (1c), or (1d) described below:

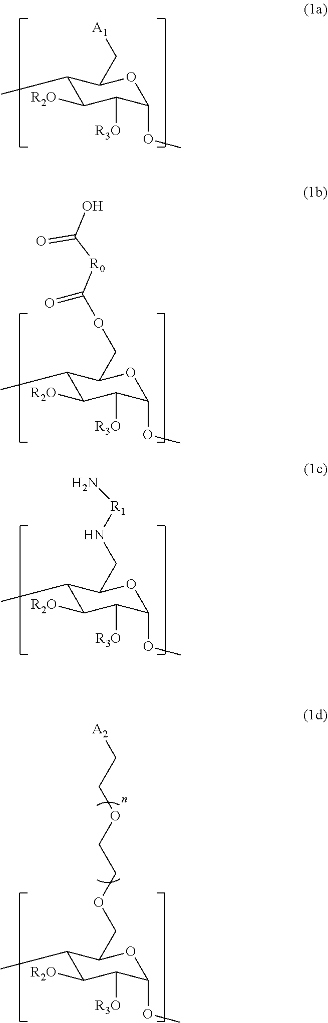

(Wherein A₁ is an amino group, an azi group, a mercapto group, a methoxy group, an acetoxy group, or a tosyloxy group, A₂ is an amino group, an azi group, a hydroxy group, or a triphenylmethyl group, R₂ and R₃ are each independently a hydrogen atom, a methyl group, an ethyl group, a propyl group, or an acetyl group, R₀ is a C₁₋₄ alkylene group or alkenylene group, R₁ is a C₂₋₄ alkylene group, and n is an integer of 2 to 8).

The solvent as the component B may further contain at least one water-soluble organic solvent selected from the group consisting of alcohols, esters, ethers, and ketones.

Further, the aqueous solution for resist pattern coating of the first aspect of the present invention optionally contains as a component C an organic sulfonic acid of Formula (2) described below:

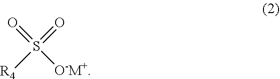

(wherein R₄ is a linear, branched, or cyclic alkyl or fluorinated alkyl group having a carbon atom number of 1 to 16, or an aromatic group having at least one of the alkyl group, the fluorinated alkyl group, a hydroxy group, or a carboxy group as a substituent, the cyclic alkyl group may have a carbonyl group in a main chain, and M⁺ is a hydrogen ion, an ammonium ion, a pyridinium ion, or an imidiazolium ion), or a salt thereof. The content of the organic sulfonic acid or the salt thereof is 0.01% by mass to 50% by mass relative to 100% by mass of the component A.

The component C is, for example, an organic sulfonate of Formula (2a) described below.

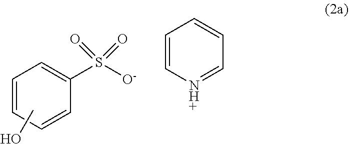

A second aspect of the present invention is a method for forming a pattern comprising steps of: exposing a resist film formed through a resist underlayer film on a substrate, baking the resist film, developing the resist film by a developer, and rinsing the resist film by a rinsing liquid through a lithography process to form a linear or columnar resist pattern; after the rinsing, applying the aqueous solution for resist pattern coating according to the first aspect of the present invention so as to cover the resist pattern without drying the resist pattern; and spin-drying the substrate having the applied aqueous solution for resist pattern coating and forming a coating film on a surface of the resist pattern with or without heating at 50° C. to 130° C.

A third aspect of the present invention is a method for forming a pattern comprising steps of: exposing a resist film formed through a resist underlayer film on a substrate, baking the resist film, developing the resist film by a developer, and rinsing the resist film by a rinsing liquid through a lithography process to form a resist pattern; after the rinsing, applying the aqueous solution for resist pattern coating according to the first aspect of the present invention further containing the component C so as to cover the resist pattern without drying the resist pattern; spin-drying the substrate having the applied aqueous solution for resist pattern coating and forming a coating film on a surface of the resist pattern with or without heating at 50° C. to 130° C.; and cooling the substrate having the coating film and etching the coating film by an etching gas to remove the coating film.

In the third aspect of the present invention, instead of etching the coating film by an etching gas after cooling the substrate having the coating film, a step of developing the coating film by a developer and a step of, after the developing the coating film, rinsing the resist pattern by a rinsing liquid may be performed.

A fourth aspect of the present invention is a method for forming an inverted pattern comprising steps of: exposing a resist film formed through a resist underlayer film on a substrate, baking the resist film, developing the resist film by a developer, and rinsing the resist film by a rinsing liquid through a lithography process to form a resist pattern; after the rinsing, applying the aqueous solution for resist pattern coating according to the first aspect of the present invention so as to cover the resist pattern without drying the resist pattern; spin-drying the substrate having the applied aqueous solution for resist pattern coating and forming a coating film on a surface of the resist pattern with or without heating at 50° C. to 130° C.; cooling the substrate having the coating film and developing the coating film by a developer; after the developing the coating film, applying a coating liquid for filling containing a polysiloxane and a solvent containing water and/or an alcohol to the resist pattern so as to fill a space in the resist pattern; removing or decreasing a component contained in the coating liquid for filling except for the polysiloxane and the developer used during the developing the coating film to form a coating film; etch-backing the coating film to expose an upper surface of the resist pattern; and removing the resist pattern having the exposed upper surface.

In the fourth aspect of the present invention, the method may further contain a step of, after the developing the coating film, rinsing the resist pattern by a rinsing liquid. After the step, a step of applying the coating liquid for filling may be carried out without drying the resist pattern.

### Effects of the Invention

When after exposure, development, and rinsing treatments of a resist film, the aqueous solution for resist pattern coating of the present invention is applied without drying a resist pattern, the thickness of the aqueous solution for resist pattern coating applied to a linear and/or columnar resist pattern formed on a substrate can be uniform. When after development and rinsing treatments, the aqueous solution for resist pattern coating of the present invention is applied without drying the resist pattern, a Laplace pressure applied to the resist pattern can be suppressed and collapse of the resist pattern can be prevented. In the aqueous solution for resist pattern coating of the present invention, water and a specific water-soluble organic solvent such as isopropyl alcohol can be optionally used as a solvent. Therefore, the aqueous solution for resist pattern coating can be used in a general development cup provided in a coater-developer due to excellent compatibility with another solution used in the development cup (e.g., a developer and a rinsing liquid containing a surfactant).

The aqueous solution for resist pattern coating of the present invention contains an organic sulfonic acid or a salt thereof. Therefore, the widths of lines in a line and space pattern of which the ratio of widths of lines is different from the ratio of widths of spaces can be uniformly reduced. Alternatively, the hole diameter of a resist pattern having holes (hereinafter, abbreviated as hole pattern in the present description) can be increased to improve the apparent sensitivity of the resist. Depending on the type of a polymer contained in the aqueous solution for resist pattern coating of the present invention, the reduction ratio of width or diameter of the resist pattern can be changed. In the further practical use of EUV exposure, a resist pattern formed through EUV exposure can be made finer.

### BRIEF DESCRIPTION OF THE DRAWINGS

FIG. 1 is an image of a resist pattern observed from a top view by a CD-SEM.

### MODES FOR CARRYING OUT THE INVENTION

<Component A>

A component A contained in an aqueous solution for resist pattern coating of the present invention is a cyclodextrin selected from the group consisting of α-cyclodextrin, β-cyclodextrin, and γ-cyclodextrin, or a derivative of the cyclodextrin. Herein, α-cyclodextrin has a cyclic structure in which six glucose units of Formula (1) described below are bonded, β-cyclodextrin has a cyclic structure in which seven glucose units of Formula (1) are bonded, and γ-cyclodextrin has a cyclic structure in which eight glucose units of Formula (1) are bonded. The derivative of the cyclodextrin has at least one glucose unit of Formula (1) in which at least one of three OH groups is substituted with a substituent. When the derivative of the cyclodextrin has one glucose unit of Formula (1) in which at least one of three OH groups is substituted with a substituent, the derivative of the cyclodextrin has further five, six, or seven glucose units of Formula (1).

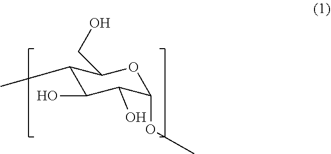

The content of the component A in the aqueous solution for resist pattern coating of the present invention is, for example, 0.01% by mass to 50% by mass, and preferably 0.1% by mass to 10% by mass, relative to 100% by mass of the aqueous solution.

<Component B>

A component B contained in the aqueous solution for resist pattern coating of the present invention is a solvent containing water as a main component. The concentration of water in the solvent containing water as a main component is, for example, 51% by mass to 100% by mass or 80% by mass to 100% by mass. A concentration of water of 100% by mass means the solvent containing water as a main component consists of water. When the solvent contains a component other than water, the component other than water is at least one water-soluble organic solvent selected from the group consisting of alcohols, esters, ethers, and ketones.

Examples of the alcohols include alcohols such as ethyl alcohol, n-propyl alcohol, isopropyl alcohol, n-butyl alcohol, sec-butyl alcohol, n-hexyl alcohol, and n-heptyl alcohol, glycol-based solvents such as ethylene glycol, propylene glycol, and diethylene glycol, and glycol ether-based solvents such as ethylene glycol monomethyl ether, propylene glycol monomethyl ether, diethylene glycol monomethyl ether, triethylene glycol monoethyl ether, and methoxymethylbutanol.

Examples of the esters include ethyl acetate, n-propyl acetate, isopropyl acetate, n-butyl acetate, propylene glycol monomethyl ether acetate, ethylene glycol monoethyl ether acetate, diethylene glycol monobutyl ether acetate, diethylene glycol monoethyl ether acetate, 3-methoxybutyl acetate, 3-methyl-3-methoxybutyl acetate, butyl lactate, and propyl lactate.

Examples of the ethers include solvents other than the glycol ether-based solvents, di-n-propyl ether, di-n-butyl ether, dioxane, and tetrahydrofuran.

Examples of the ketones include 1-octanone, 2-octanone, 1-nonanone, 2-nonanone, 4-heptanone, 1-hexanone, 2-hexanone, diisobutyl ketone, cyclohexanone, methyl ethyl ketone, methyl isobutyl ketone, and acetophenone.

<Component C>

The aqueous solution for resist pattern coating of the present invention may further contain an organic sulfonic acid of Formula (2) described above or a salt thereof as a component C. Examples of the organic sulfonic acid include octylbenzenesulfonic acid, nonylbenzenesulfonic acid, decylbenzenesulfonic acid, undecylbenzenesulfonic acid, dodecylbenzenesulfonic acid (alias name: laurylbenzenesulfonic acid), (1,3,5,7-tetramethyloctyl)benzensulfonic acid, tridecylbenzenesulfonic acid, (1R)-(−)-10-camphorsulfonic acid, (1S)-(+)-10-camphorsulfonic acid, trifluoromethanesulfonic acid, perfluorobutanesulfonic acid, perfluorooctanesulfonic acid, nonafluoro-1-butanesulfonic acid, p-toluenesulfonic acid, and 1-naphthalenesulfonic acid. Examples of the salt of the organic sulfonic acid include pyridinium p-toluenesulfonate, pyridinium p-phenolsulfonate, ammonium p-toluenesulfonate, ammonium p-phenolsulfonate, imidiazolium p-toluenesulfonate, and imidiazolium p-phenolsulfonate. Among the organic sulfonic acids or salts thereof, pyridinium p-phenolsulfonate is preferably used as the component C contained in the aqueous solution for resist pattern coating of the present invention.

When the aqueous solution for resist pattern coating of the present invention contains the component C, the content of the component C is, for example, 0.01% by mass to 50% by mass, and preferably 0.01% by mass to 30% by mass or 0.01% by mass to 20% by mass, relative to 100% by mass of the component A.

<Other Additive>

The aqueous solution for resist pattern coating of the present invention may further contain various additives such as a surfactant, if necessary, as long as the effects of the present invention are not impaired. The surfactant is an additive for improving the application properties of the aqueous solution to a substrate. A publicly known surfactant such as a nonionic surfactant or a fluorosurfactant can be used.

Specific examples of the surfactant include nonionic surfactants including polyoxyethylene alkyl ethers such as polyoxyethylene lauryl ether, polyoxyethylene stearyl ether, polyoxyethylene cetyl ether, and polyoxyethylene oleyl ether, polyoxyethylene alkylaryl ethers such as polyoxyethylene octylphenyl ether and polyoxyethylene nonylphenyl ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, fluorosurfactants including Eftop [registered trademark] EF301, EF303, and EF352 [available from Mitsubishi Materials Electronic Chemicals Co., Ltd.], MEGAFACE [registered trademark] F171, F173, R-30, R-40, and R-40-LM (available from DIC Corporation), Fluorad FC430 and FC431 (available from Sumitomo 3M, Ltd.), and Asahi Guard [registered trademark] AG710, and Surfion [registered trademark] S-382, SC101, SC102, SC103, SC104, SC105, and SC106 (available from Asahi Glass Co., Ltd.), and organosiloxane polymer KP341 (available from Shin-Etsu Chemical Co., Ltd.). One type of the surfactant may be added alone or two or more types thereof may be added in combination.

When the aqueous solution for resist pattern coating of the present invention contains the surfactant, the content of the surfactant is, for example, 0.1% by mass to 5% by mass, and preferably 0.2% by mass to 3% by mass, relative to 100% by mass of the component A in the aqueous solution.

[Method for Forming Pattern and Method for Forming Inverted Pattern]

A method for forming a pattern and a method for forming an inverted pattern using the aqueous solution for resist pattern coating of the present invention include a step of exposing a resist film formed on a substrate through a resist underlayer film, baking the resist film, developing the resist film by a developer, and rinsing the resist film by a rinsing liquid through a lithography process to form a resist pattern. Examples of the substrate include substrates used in production of precision integrated circuit elements (e.g., a semiconductor substrate such as a silicon wafer that may be coated with a silicon oxide film, a silicon nitride film, or a silicon nitride oxide film, a silicon nitride substrate, a quartz substrate, an alkali-free glass substrate, a low alkaline glass substrate, a crystalline glass substrate, and a glass substrate having an ITO film). On the substrate, an organic film and/or inorganic film having an anti-reflective performance are/is formed as a resist underlayer film. As a resist solution used to form a resist film on a substrate having the resist underlayer film, a positive resist solution (e.g., PAR710 and PAR855 available from Sumitomo Chemical Co., Ltd., and AR2772JN available from JSR Corporation) can be used. Instead of the positive resist solution, a negative resist solution can be also used.

As a light source of an exposure apparatus used in exposure of the resist film, for example, radiation selected from the group consisting of an i-line, a KrF excimer laser, an ArF excimer laser, and EUV can be used. The heating temperature in post exposure bake (PEB) of the exposed resist film is, for example, 80° C. to 140° C.

When the positive resist solution is used in formation of the resist film, examples of the developer used in the development treatment include aqueous solutions of alkalis including inorganic alkalis such as sodium hydroxide, potassium hydroxide, sodium carbonate, sodium silicate, sodium methasilicate, and ammonia water, primary amines such as ethylamine and n-propylamine, secondary amines such as diethylamine and di-n-butylamine, tertiary amines such as triethylamine and methyldiethylamine, alcoholamines such as dimethylethanolamine and triethanolamine, quaternary ammonium salts such as tetramethylammonium hydroxide, tetraethylammonium hydroxide, and choline, and cyclic amines such as pyrrole and piperidine. A solution in which proper amounts of an alcohol such as isopropyl alcohol and a surfactant such as a nonionic surfactant are added to the aqueous solution of the alkali may also be used. Among the developers, an aqueous solution of quaternary ammonium salt is preferable, and an aqueous solution of tetramethylammonium hydroxide is further preferable.

Examples of the shape of the resist pattern to be formed include a line and a column, and the resist pattern may include a hole pattern. In a case of forming a linear resist pattern, the formed resist pattern may be an isolated line pattern or a line and space pattern. The shape of the linear resist pattern is not limited to a line, and may be a bent shape.

Examples of the rinsing liquid used in the rinsing treatment include an aqueous solution containing a surfactant, pure water, and ultrapure water.

The method for forming a pattern and the method for forming an inverted pattern using the aqueous solution for resist pattern coating of the present invention include a step of, after the rinsing, applying the aqueous solution for resist pattern coating of the present invention so as to cover the resist pattern. In the step, it is important that the resist pattern is not dried. This is because the resist pattern may collapse during drying the resist pattern.

When a coating film that has been formed on a surface of the resist pattern is etched by an etching gas, examples of the etching gas include a mixed gas of O₂ and N₂, an O₂ gas, a CF₄ gas, a Cl₂ gas, a HBr gas, a SiF₄ gas, a HCl gas, a He gas, and an Ar gas. Alternatively, when the coating film is subjected to development by a developer, the aqueous solution of the alkali can be used as the developer. As the rinsing liquid used in a rinsing treatment after the development, the rinsing liquid exemplified above can be used.

<Coating Liquid for Filling>

The method for forming an inverted pattern using the aqueous solution for resist pattern coating of the present invention includes a step of applying a coating liquid for filling containing a polysiloxane and a solvent containing water and/or an alcohol so as to fill a space in the resist pattern. As the polysiloxane that is a component of the coating liquid for filling, a publicly known material used for a coating liquid applied to a resist pattern can be used. As the alcohol, the alcohol that is the component of the component C except for water exemplified above can be used.

The method for forming an inverted pattern using the aqueous solution for resist pattern coating of the present invention further includes a step of removing or decreasing a component contained in the coating liquid for filling except for the polysiloxane and the rinsing liquid to form a coating film. In the step, for example, the substrate coated with the coating liquid for filling is spin-dried or spin-dried and heated. Herein, the spin-drying is drying under rotation of the substrate. The component contained in the coating liquid for filling except for the polysiloxane includes a polysiloxane, a solvent containing water and/or an alcohol, and an additive to be added if necessary.

The method for forming an inverted pattern using the aqueous solution for resist pattern coating of the present invention further includes steps of etch-backing the coating film to exposure an upper surface of the resist pattern and removing the resist pattern having the exposed upper surface. For example, the etch-backing is carried out by dry etching by a fluorine-containing gas such as CF₄, wet etching by an aqueous solution of organic acid or organic base, wet etching by an organic solvent, or a CMP method. A treatment condition can be appropriately adjusted. In the removal of the resist pattern having the exposed upper surface, for example, dry etching by a mixed gas of O₂ and N₂ or an O₂ gas is carried out.

### EXAMPLES

### Example 1

In 38.80 g of pure water, 1.20 g of α-cyclodextrin (available from Tokyo Chemical Industry Co., Ltd.) was dissolved. The mixture was then filtered through a microfilter having a pore diameter of 0.20 μm (manufactured by GE Healthcare Japan Corporation (Whatman)) to prepare an aqueous solution for resist pattern coating.

### Example 2

In 37.80 g of pure water, 2.20 g of α-cyclodextrin (available from Tokyo Chemical Industry Co., Ltd.) was dissolved. The mixture was then filtered through a microfilter having a pore diameter of 0.20 μm (manufactured by GE Healthcare Japan Corporation (Whatman)) to prepare an aqueous solution for resist pattern coating.

### Example 3

In 38.38 g of pure water, 1.58 g of α-cyclodextrin (available from Tokyo Chemical Industry Co., Ltd.) and 0.35 g of pyridinium p-phenolsulfonate were dissolved. The mixture was then filtered through a microfilter having a pore diameter of 0.20 μm (manufactured by GE Healthcare Japan Corporation (Whatman)) to prepare an aqueous solution for resist pattern coating.

### Comparative Example 1

In 38.80 g of pure water, 1.20 g of 18-crown-6-ether (available from Tokyo Chemical Industry Co., Ltd.) was dissolved. The mixture was then filtered through a microfilter having a pore diameter of 0.20 μm (manufactured by GE Healthcare Japan Corporation (Whatman)) to prepare an aqueous solution for resist pattern coating.

[Test of Application Properties to Silicon Wafer]

Pure water was added to the aqueous solution for resist pattern coating prepared in each of Examples 1 to 3 and Comparative Example 1, the obtained aqueous solution was applied to a silicon wafer by a spin coater (at 1,500 rpm for 60 seconds) so that the thickness was 50 nm or 100 nm, and the silicon wafer was baked at 100° C. for 60 seconds. After then, the coating film on the silicon wafer was checked. The application properties of each of the aqueous solutions for resist pattern coating to the silicon wafer were evaluated. The results are shown in Table 1. In Table 1, a case where the aqueous solution for resist pattern coating is uniformly applied to the silicon wafer is determined to be “good.” A case where the aqueous solution for resist pattern coating is applied to the silicon wafer in an ununiform state is determined to be “poor coating.”

TABLE 1

| | Application properties |
|---|---|
| | to silicon wafer |
| Example 1 | Good |
| Example 2 | Good |
| Example 3 | Good |
| Comparative Example 1 | Poor coating |

[Formation of Photoresist Pattern]

A resist underlayer film-forming composition described in Comparative Example 1 of International publication WO 2015/046149 was applied to a silicon wafer by a spinner. The silicon wafer was disposed on a hot plate and heated at 205° C. for one minute to form a resist underlayer film having a thickness of 80 nm. A commercially available photoresist solution (trade name: PAR855 available from Sumitomo Chemical Co., Ltd.) was applied to the resist underlayer film by a spinner, and the silicon wafer was heated on a hot plate at 105° C. for 60 seconds to form a photoresist film (thickness: 0.10 μm).

The photoresist film was then exposed through a photomask by a scanner (NSR-S307E manufactured by Nikon Corporation (wavelength: 193 nm, NA: 0.85, σ: 0.65/0.93)). The photomask was selected depending on a resist pattern to be formed. After the exposure, post exposure bake (PEB) was carried out at 105° C. for 60 seconds on a hot plate. After cooling, development was carried out using a 0.26 N tetramethylammonium hydroxide aqueous solution as a developer by a 60-second single puddle process in accordance with industrial standard. To remove the developer, the photoresist film was coated and rinsed with pure water, and dried by spin-drying. By the processes described above, a target resist pattern was formed. In the formed line and space pattern, the widths of line pattern were measured and the presence or absence of pattern collapse was checked.

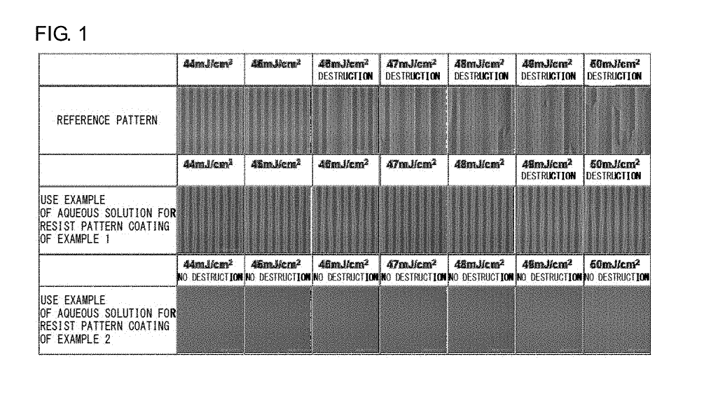

The resist pattern that had been formed by the processes was observed from a top view by CD-SEM S-9380II (manufactured by Hitachi High-Technologies Corporation) and an image thereof was obtained. For confirmation of an effect for preventing collapse of the resist pattern, a step of applying the aqueous solution for resist pattern coating prepared in each of Examples 1 and 2 by a spin coater (at 1,500 rpm for 60 seconds) so as to over the resist pattern after exposure, development, and rinsing treatments and before drying the resist pattern formed on the silicon wafer was carried out, and the silicon wafer was then baked at 100° C. for 60 seconds to form a coating film. The results are shown in FIG. 1. The resist pattern after the exposure, development, and rinsing treatments was dried without applying the aqueous solution for resist pattern coating, and used as a reference. In comparison between the resist patterns having the coating films formed using the aqueous solution for resist pattern coating of Examples 1 and 2, the resist patterns were exposed after formation of the coating films while the exposure dose (mJ/cm²) was increased by 1 mJ/cm², and the resist patterns were narrowed. Even in this case, suppressing collapse of the resist patterns was confirmed. In FIG. 1 in which the resist patterns were observed by the CD-SEM, a case where collapse of the resist pattern was confirmed and a case where bending or curling of the resist pattern was confirmed were determined to be “destruction.”

[Test of Miniaturization of Resist Pattern]

A resist underlayer film-forming composition described in Example 1 of International publication WO 2015/046149 was applied to a silicon wafer by a spinner so that the thickness was 5 nm. The silicon wafer was disposed on a hot plate and heated at 205° C. for one minute to form a resist underlayer film. To the resist underlayer film, an EUV resist was applied so that the thickness was 40 nm, and the silicon wafer was baked. By an EUV exposure apparatus NXE3300 manufactured by ASML Holding N.V., a resist film on which a line and space pattern was drawn was produced on the silicon wafer. This silicon wafer was cut into chips, and development was carried out using a 0.26 N tetramethylammonium hydroxide aqueous solution as a developer. To remove the developer, the resist film was coated and rinsed with pure water, and dried on a hot plate at 100° C. for 30 seconds, to obtain a 1:1 line and space pattern as a reference. Additionally, for the silicon wafer cut into chips that was produced by the aforementioned procedure, development was carried out using the developer. To remove the developer, the silicon wafer was rinsed with pure water. After then, the aqueous solution for resist pattern coating prepared in Example 3 was applied to the resist pattern after the development and rinsing treatments and before drying, and baked at 70° C. for 60 seconds to form a coating film. The coating film was developed by a developer, and the resist pattern after developing the coating film by the developer was rinsed by a rinsing liquid, and dried at 100° C. for 30 seconds to trim the width of the line pattern. The width of the line pattern was measured. The results are shown in Table 2 described below. In Table 2, a case where the obtained resist pattern was confirmed to be a rectangle pattern in which no collapse or destruction occurred was determined to be a “good” pattern shape. The results of Table 2 show that in comparison of the pattern obtained by development, rinsing, and drying after formation of the coating film from the aqueous solution for resist pattern coating of Example 3 with the reference pattern, the line pattern width was decreased to 2 nm. The roughness (LWR) in the line and space pattern having the coating film was measured. The LWR is abbreviation of “Line Width Roughness.”

TABLE 2

| | | Using aqueous |
|---|---|---|
| | | solution for |
| | | resist pattern coating of |
| | Reference | Example 3 |
| Pattern shape | Good | Good |
| Line pattern width/nm | 21 | 19 |
| Trimming amount/nm | — | 2 |
| Roughness (LWR)/nm | 2.4 | 2.3 |

1. An aqueous solution for resist pattern coating comprising, as an A component, a cyclodextrin selected from the group consisting of α-cyclodextrin, β-cyclodextrin, and γ-cyclodextrin, or a derivative of the cyclodextrin, and as a B component, a solvent containing water as a main component, wherein the content of the A component is 0.1% by mass to 10% by mass relative to 100% by mass of the aqueous solution.

2. The aqueous solution for resist pattern coating according to claim 1, wherein the derivative of the cyclodextrin is a compound having at least one unit of Formula (1a), (1b), (1c), or (1d) described below: 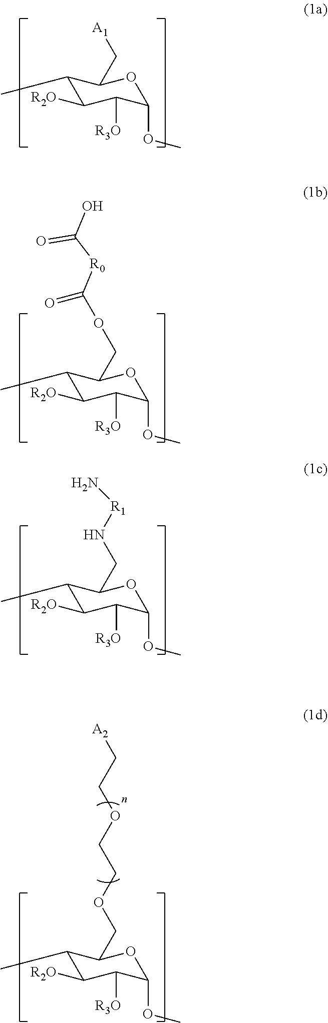
wherein A₁ is an amino group, an azi group, a mercapto group, a methoxy group, an acetoxy group, or a tosyloxy group, A₂ is an amino group, an azi group, a hydroxy group, or a triphenylmethyl group, R₂ and R₃ are each independently a hydrogen atom, a methyl group, an ethyl group, a propyl group, or an acetyl group, R₀ is a C₁₋₄ alkylene or alkenylene group, R₁ is a C₂₋₄ alkylene group, and n is an integer of 2 to 8.

3. The aqueous solution for resist pattern coating according to claim 1, wherein the solvent as the component B further contains at least one water-soluble organic solvent selected from the group consisting of alcohols, esters, ethers, and ketones.

4. The aqueous solution for resist pattern coating according to claim 1, further comprising, as a component C, an organic sulfonic acid of Formula (2): 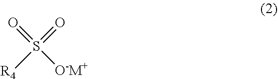
wherein R₄ is a linear, branched, or cyclic alkyl or fluorinated alkyl group having a carbon atom number of 1 to 16, or an aromatic group having at least one of the alkyl group, the fluorinated alkyl group, a hydroxy group, or a carboxy group as a substituent, the cyclic alkyl group may have a carbonyl group in a main chain, and M⁺ is a hydrogen ion, an ammonium ion, a pyridinium ion, or an imidiazolium ion or a salt thereof, wherein the content of the organic sulfonic acid or the salt thereof is 0.01% by mass to 50% by mass relative to 100% by mass of the component A.

5. The aqueous solution for resist pattern coating according to claim 4, wherein the component C is an organic sulfonate of Formula (2) described below.

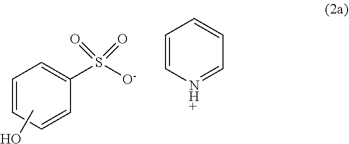

6. A method for forming a pattern comprising steps of:
exposing a resist film formed on a substrate through a resist underlayer film, baking the resist film, developing the resist film by a developer, and rinsing the resist film by a rinsing liquid through a lithography process to form a linear or columnar resist pattern;
after the rinsing, applying the aqueous solution for resist pattern coating according to claim 1 so as to cover the resist pattern without drying the resist pattern; and
spin-drying the substrate coated with the aqueous solution for resist pattern coating and forming a coating film on a surface of the resist pattern with or without heating at 50° C. to 130° C.

7. A method for forming a pattern comprising steps of:
exposing a resist film formed on a substrate through a resist underlayer film, baking the resist film, developing the resist film by a developer, and rinsing the resist film by a rinsing liquid through a lithography process to form a resist pattern;
after the rinsing, applying the aqueous solution for resist pattern coating according to claim 4 so as to cover the resist pattern without drying the resist pattern;
spin-drying the substrate coated with the aqueous solution for resist pattern coating and forming a coating film on a surface of the resist pattern with or without heating at 50° C. to 130° C.; and
cooling the substrate having the formed coating film and etching the coating film by an etching gas to remove the coating film.

8. A method for forming a pattern comprising steps of:
exposing a resist film formed on a substrate through a resist underlayer film, baking the resist film, developing the resist film by a developer, and rinsing the resist film by a rinsing liquid through a lithography process to form a resist pattern;
after the rinsing, applying the aqueous solution for resist pattern coating according to claim 4 so as to cover the resist pattern without drying the resist pattern;
spin-drying the substrate coated with the aqueous solution for resist pattern coating and forming a coating film on a surface of the resist pattern with or without heating at 50° C. to 130° C.;
cooling the substrate having the coating film and developing the coating film by a developer; and
after the developing the coating film, rinsing the resist pattern by a rinsing liquid.

9. A method for forming an inverted pattern comprising steps of:
exposing a resist film formed on a substrate through a resist underlayer film, baking the resist film, developing the resist film by a developer, and rinsing the resist film by a rinsing liquid through a lithography process to form a resist pattern;
after the rinsing, applying the aqueous solution for resist pattern coating according to claim 1 so as to cover the resist pattern without drying the resist pattern;
spin-drying the substrate coated with the aqueous solution for resist pattern coating and forming a coating film on a surface of the resist pattern with or without heating at 50° C. to 130° C.;
cooling the substrate having the coating film and developing the coating film by a developer;
after the developing the coating film, applying a coating liquid for filling containing a polysiloxane and a solvent containing water and/or an alcohol so as to fill a space in the resist pattern;
removing or decreasing a component contained in the coating liquid for filling except for the polysiloxane and the developer used during developing the coating film to form a coating film;
etch-backing the coating film to expose an upper surface of the resist pattern; and
removing the resist pattern having the exposed upper surface.

10. A method for forming an inverted pattern comprising steps of:
exposing a resist film formed on a substrate through a resist underlayer film, baking the resist film, and developing the resist film by a developer through a lithography process to form a resist pattern;
applying the aqueous solution for resist pattern coating according to claim 1 so as to cover the resist pattern;
spin-drying the substrate coated with the aqueous solution for resist pattern coating and forming a coating film on a surface of the resist pattern with or without heating at 50° C. to 130° C.;
cooling the substrate having the coating film and developing the coating film by a developer;
after the developing the coating film, rinsing the resist pattern by a rinsing liquid;
after the rinsing, applying a coating liquid for filling containing a polysiloxane and a solvent containing water and/or an alcohol so as to fill a space in the resist pattern without drying the resist pattern;
removing or decreasing a component contained in the coating liquid for filling except for the polysiloxane and the rinsing liquid to form a coating film;
etch-backing the coating film to expose an upper surface of the resist pattern; and
removing the resist pattern having the exposed upper surface.
